(19) United States
(12) Patent Application Publication
(10) Pub. No.: US 2025/0277877 A1
(43) Pub. Date: Sep. 4, 2025

(54) METHODS OF TESTING A PROCESS WINDOW, AND AUTOMATICALLY OPTIMIZING A PROCESS, ON A WIRE BONDING SYSTEM

(71) Applicant: Kulicke and Soffa Industries, Inc., Fort Washington, PA (US)

(72) Inventors: Hui Xu, Chalfont, PA (US); Wei Qin, Ambler, PA (US); Aashish Shah, Chalfont, PA (US); JeongHo Yang, Blue Bell, PA (US); Gary S. Gillotti, North Wales, PA (US)

(73) Assignee: Kulicke and Soffa Industries, Inc., Fort Washington, PA (US)

(21) Appl. No.: 19/056,020

(22) Filed: Feb. 18, 2025

Related U.S. Application Data
(60) Provisional application No. 63/560,190, filed on Mar. 1, 2024.

(51) Int. Cl. G01R 31/66

(52) U.S. Cl. CPC G01R 31/66

(57) ABSTRACT

A method of testing a process window for a process parameter on a wire bonding system is provided. The method includes the steps of: (a) identifying the process parameter utilized in a wire bonding operation on the wire bonding system; (b) testing at least one response of the process parameter at a plurality of values of the process parameter on the wire bonding system; and (c) automatically recording the at least one response of the process parameter at the plurality of values of the process parameter.

### CROSS-REFERENCE TO RELATED APPLICATION

This application claims the benefit of U.S. Provisional Application No. 63/560,190, filed Mar. 1, 2024, the content of which is incorporated herein by reference.

### FIELD

The invention relates to wire bonding operations, and in particular, to methods of testing a process window for a process parameter on a wire bonding system.

### BACKGROUND

In the processing and packaging of semiconductor devices, wire bonding continues to be a primary method of providing electrical interconnection between two locations within a package (e.g., between a die pad of a semiconductor die and a lead of a leadframe). More specifically, using a wire bonder (also known as a wire bonding machine) wire loops are formed between respective locations to be electrically interconnected. The primary methods of forming wire loops are ball bonding and wedge bonding. In forming the bonds between (a) the ends of the wire loop and (b) respective bonding locations (e.g., a die pad, a lead, etc.), varying types of bonding energy may be used, for example, ultrasonic energy, thermosonic energy, thermocompressive energy, amongst others. Wire bonding machines (e.g., stud bumping machines) are also used to form conductive bumps from portions of wire.

During ball bonding operations, a tail of wire extending from the tip of a bonding tool (e.g., a capillary) is melted into a free air ball using a spark from an electronic flame-off (EFO) device. The free air ball is then used to form a first bond (e.g., a ball bond) of a wire loop at a first bonding location, and then wire is extended from the ball bond to a second bonding location, where a second bond (e.g., a stitch bond) of the wire loop is formed by bonding a portion of the wire to the second bonding location using the bonding tool. For example, the first bonding location may be a bonding pad of a semiconductor die, and the second bonding location may be a lead of a leadframe.

In connection with such wire bonding operations, a number of challenging situations may occur. For example, during bonding of a first bond of a wire loop, the free air ball may not be properly bonded to a bonding location. This situation is sometimes referred to as an NSOP condition (i.e., a no stick on pad condition). In another example, a second bond of a wire loop may not be properly bonded to a bonding location. This situation is sometimes referred to as an NSOL condition (i.e., a no stick on lead condition). Exemplary processes for addressing such “no stick” conditions are disclosed in U.S. Pat. No. 8,899,469 entitled “AUTOMATIC REWORK PROCESSES FOR NON-STICK CONDITIONS IN WIRE BONDING OPERATIONS”.

Another challenge in wire bonding operations relates to a so called “short tail condition.” For example, after formation of a stitch bond at a second bond location of a wire loop, a bonding tool may be raised to a short tail detect height where the wire is tested (e.g., an electrical continuity test) to ensure it is still continuous with the stitch bond on the second bonding location. If a short tail is not detected, the bond head (i.e., carrying the bonding tool and a wire clamp, now closed) is raised to tear the wire at the stitch bond. The remaining wire tail length may then be used to form another free air ball for another wire loop. However, a short tail may be detected. Short tail conditions may result in a number of problems during wire bonding such as, for example, inconsistent free air ball size and shape. Exemplary techniques for addressing such “short tail” conditions are disclosed in U.S. Pat. No. 9,165,842 entitled “SHORT TAIL RECOVERY TECHNIQUES IN WIRE BONDING OPERATIONS”. The content of each of U.S. Pat. Nos. 8,899,469 and 9,165,842 is incorporated by reference herein in their entirety.

Certain process parameters used in connection with wire bonding operations may be modified to address certain undesirable conditions (e.g., NSOP, NSOL, etc.). Thus, it would be desirable to provide a method of testing a process window for such a process parameter on a wire bonding system.

### SUMMARY

According to an exemplary embodiment of the invention, a method of testing a process window for a process parameter on a wire bonding system is provided. The method includes the steps of: (a) identifying the process parameter utilized in a wire bonding operation on the wire bonding system; (b) testing at least one response of the process parameter at a plurality of values of the process parameter on the wire bonding system; and (c) automatically recording the at least one response of the process parameter at the plurality of values of the process parameter.

According to other embodiments of the invention, the method recited in the immediately preceding paragraph may have any one or more of the following features: further including a step of (d) identifying an acceptable process window for the process parameter based on the results of step (b); further including a step of identifying an optimal value of the process parameter based on the results of step (b); further including a step of automatically recovering from a process error during step (b) without operator intervention; the step of automatically recovering from the process error includes at least one of recovering from a ball lift condition, recovering from a stitch lift condition, recovering from a short tail condition, bonding a lifted ball to another location and continuing with step (b), utilizing predetermined parameters for forming a wire tail after bonding the lifted ball, bonding a lifted stitch to another location and continuing with step (b), and/or utilizing predetermined parameters for forming a wire tail after bonding the lifted stitch; the process parameter relates to at least one of ultrasonic energy applied during formation of a wire bond (e.g., a ball bond of a wire loop, a stitch bond of a wire loop, a first wire bond of a wire loop, a second wire bond of a wire loop, an intermediate wire bond of a wire loop, a conductive bump bond, a wire bond of vertical wire structure, etc.), bonding force applied during formation of a wire bond, and table scrub energy applied during formation of a wire bond; the at least one response relates to at least one of ball lift of a ball bond, stitch lift of a stitch bond, a short tail condition, a pull value of a wire bond, a shape of a wire bond, and/or a dimension of a wire bond; each of steps (b) and (c) are repeated for a predetermined number of iterations at each of the plurality of values of the process parameter; each of steps (b) and (c) is repeated while varying another process parameter to test the at least one response of the process parameter at the plurality of values of the process parameter, and the another process parameter, on the wire bonding system; further including a step of (d) identifying an acceptable process window for the process parameter, and a desirable value of the another process parameter, after the repeated steps (b) and (c); and/or further including a step of identifying an optimal value of the process parameter, and a desirable value of the another process parameter, after the repeated steps (b) and (c).

According to another exemplary embodiment of the invention, a method of testing a process window for a process parameter on a wire bonding system is provided. The method includes the steps of: (a) identifying the process parameter utilized in a wire bonding operation on the wire bonding system; (b) testing at least one response of the process parameter at a plurality of values of the process parameter on the wire bonding system; and (c) identifying an acceptable process window for the process parameter based on the results of step (b).

According to other embodiments of the invention, the method recited in the immediately preceding paragraph may have any one or more of the following features: further including a step of automatically recording the at least one response of the process parameter at the plurality of values of the process parameter; the at least one response relates to at least one of ball lift of the ball bond, stitch lift of a stitch bond, a short tail condition, a pull value of a wire bond, a shape of a wire bond, and/or a dimension of a wire bond; the process parameter relates to at least one of ultrasonic energy applied during formation of a wire bond (e.g., a first wire bond of a wire loop, a second wire bond of a wire loop, an intermediate wire bond of a wire loop, a conductive bump bond, a wire bond of vertical wire structure, a ball bond of a wire loop, a stitch bond of a wire loop, etc.), bonding force applied during formation of a wire bond, and table scrub energy applied during formation of a wire bond; further including a step of identifying an optimal value of the process parameter based on the results of step (b); further including a step of automatically recovering from a process error during step (b) without operator intervention; the step of automatically recovering from the process error includes at least one of recovering from a ball lift condition, recovering from a stitch lift condition, recovering from a short tail condition, bonding a lifted ball to another location, and continuing with step (b), bonding a lifted stitch to another location and continuing with step (b), and/or utilizing predetermined parameters for forming a wire tail after bonding the lifted ball; step (b) is repeated for a predetermined number of iterations at each of the plurality of values of the process parameter prior to step (c); step (b) is repeated while varying another process parameter to test the at least one response of the process parameter at the plurality of values of the process parameter, and the another process parameter, on the wire bonding system, prior to step (c); further including a step of (d) identifying a desirable value of the another process parameter, after the repeated step (b); and/or further including a step of identifying an optimal value of the process parameter, and a desirable value of the another process parameter, after the repeated step (b).

According to another exemplary embodiment of the invention, a method of testing a process window for a process parameter on a wire bonding system is provided. The method includes the steps of: (a) identifying the process parameter utilized in a wire bonding operation on a wire bonding system; (b) testing at least one response of the process parameter at a plurality of values of the process parameter on the wire bonding system; and (c) identifying an optimal value of the process parameter based on the results of step (b).

According to other embodiments of the invention, the method recited in the immediately preceding paragraph may have any one or more of the following features: further including a step of (d) identifying an acceptable process window for the process parameter based on the results of step (b); further including a step of automatically recording the at least one response of the process parameter at the plurality of values of the process parameter; the at least one response relates to at least one of ball lift of the ball bond, stitch lift of a stitch bond, a short tail condition, a pull value of a wire bond, a shape of a wire bond, and/or a dimension of a wire bond; the process parameter relates to at least one of ultrasonic energy applied during formation of a wire bond (e.g., a first wire bond of a wire loop, a second wire bond of a wire loop, an intermediate wire bond of a wire loop, a conductive bump bond, a wire bond of vertical wire structure, a ball bond of a wire loop, a stitch bond of a wire loop, etc.), bonding force applied during formation of a wire bond, and table scrub energy applied during formation of a wire bond; further including a step of automatically recovering from a process error during step (b) without operator intervention; the step of automatically recovering from the process error includes at least one of recovering from a ball lift condition, recovering from a stitch lift condition, recovering from a short tail condition, bonding a lifted ball to another location and continuing with step (b), utilizing predetermined parameters for forming a wire tail after bonding the lifted ball, bonding a lifted stitch to another location and continuing with step (b), and/or utilizing predetermined parameters for forming a wire tail after bonding the lifted stitch; step (b) is repeated for a predetermined number of iterations at each of the plurality of values of the process parameter prior to step (c); step (b) is repeated while varying another process parameter to test the at least one response of the process parameter at the plurality of values of the process parameter, and the another process parameter, on the wire bonding system, prior to step (c); further including a step of (d) identifying an acceptable process window for the process parameter, and a desirable value of the another process parameter, after the repeated step (b); and/or further including a step of identifying a desirable value of the another process parameter, after the repeated step (b).

The methods of the present invention may also be embodied as an apparatus (e.g., as part of the intelligence of a wire bonding machine/system), or as computer program instructions on a computer readable carrier (e.g., a computer readable carrier including a wire bonding program used in connection with a wire bonding machine/system).

### BRIEF DESCRIPTION OF THE DRAWINGS

The invention is best understood from the following detailed description when read in connection with the accompanying drawings. It is emphasized that, according to common practice, the various features of the drawings are not to scale. On the contrary, the dimensions of the various features are arbitrarily expanded or reduced for clarity. Included in the drawings are the following figures:

FIGS. 1A-1B are block diagram side views of a wire bonding system illustrating testing of a process parameter in accordance with certain exemplary embodiments of the invention;

FIGS. 2A-2B are block diagram side views of the wire bonding system of FIGS. 1A-1B illustrating further testing of a process parameter in accordance with certain exemplary embodiments of the invention;

FIGS. 3A-3B are block diagram side views of the wire bonding system of FIGS. 1A-1B illustrating further testing of a process parameter in accordance with certain exemplary embodiments of the invention;

FIGS. 4A-4B are block diagram side views of the wire bonding system of FIGS. 1A-1B illustrating further testing of a process parameter in accordance with certain exemplary embodiments of the invention;

FIGS. 5A-5B are block diagram side views of the wire bonding system of FIGS. 1A-1B illustrating further testing of a process parameter in accordance with certain exemplary embodiments of the invention;

FIGS. 6A-6B are block diagram side views of the wire bonding system of FIGS. 1A-1B illustrating further testing of a process parameter in accordance with certain exemplary embodiments of the invention;

FIGS. 7A-7C are block diagram side views of the wire bonding system of FIGS. 1A-1B illustrating further testing of a process parameter in accordance with certain exemplary embodiments of the invention;

FIGS. 8A-8C are block diagram side views of the wire bonding system of FIGS. 1A-1B illustrating further testing of a process parameter in accordance with certain exemplary embodiments of the invention;

FIGS. 9A-9C are block diagram side views of the wire bonding system of FIGS. 1A-1B illustrating further testing of a process parameter in accordance with certain exemplary embodiments of the invention; and

FIG. 10 is a flow diagram illustrating a method of automatically testing a process window for a process parameter on a wire bonding system in accordance with various exemplary embodiments of the invention.

### DETAILED DESCRIPTION

As used herein, the term “semiconductor element” is intended to refer to any structure including (or configured to include at a later step) a semiconductor chip or die. Exemplary semiconductor elements include a bare semiconductor die, a semiconductor die on a substrate (e.g., a leadframe, a PCB, a carrier, etc.), a packaged semiconductor device, a flip chip semiconductor device, a die embedded in a substrate, a stack of semiconductor die, amongst others. Further, the semiconductor element may include an element configured to be bonded or otherwise included in a semiconductor package (e.g., a spacer to be bonded in a stacked die configuration, a substrate, etc.). In connection with the invention, a semiconductor element is an example of a workpiece. Another example of a workpiece is a semiconductor element mounted on a substrate (e.g., a semiconductor die mounted on a leadframe). Yet another example of a workpiece is a plurality of semiconductor elements.

As used herein, the term “process parameter” is intended to be broadly construed to include any parameter or setting used in a wire bonding process (e.g., USG, bond force, scrub amplitude, scrub frequency, time, bonding duration, bonding system settings, bonding system modes, etc.). Values of process parameters can be any quantitative and/or qualitative value (e.g., numerical value, percentage of a baseline/setpoint, on/off condition, operating/not operating in a mode, etc.).

As will be appreciated by those skilled in the art, the term “wire portion” is intended to be broadly construed, and not limited to any exact length.

Various error conditions of a wire bonding process are described herein. Such error conditions can include NSOP conditions, NSOL conditions, short tail conditions, long tail conditions, amongst others.

According to certain exemplary embodiments of the invention, a software feature is provided on a wire bonding system that allows for automatic process window testing on the wire bonding system. Exemplary process windows being tested include: a USG window; a bond force process window; and a scrub amplitude process window. Such process windows may be tested for various wire bonds, for example, a first wire bond of a wire loop (e.g., a ball bond), a second bond of a wire loop (e.g., a stitch bond), etc. Exemplary process responses used in connection with the testing of a process window include a ball lift response, a stitch lift response, a short tail response, a pull test response (e.g., using a pull tester integrated with the wire bonding system), and a shear test response (e.g., using a shear tester integrated with the wire bonding system).

For example, if a USG process window is to be tested, multiple values (e.g., levels of an input setting, percentages of a baseline setpoint, etc.) are tested, where process responses (e.g., ball lift) are automatically determined and recorded on the wire bonding system. According to certain exemplary embodiments of the invention, the methods include automatic recovery mechanisms to address process error conditions (e.g., a ball lift condition).

It should be understood that like reference numbers used in the present specification (including drawings) are intended to refer to like elements unless indicated otherwise.

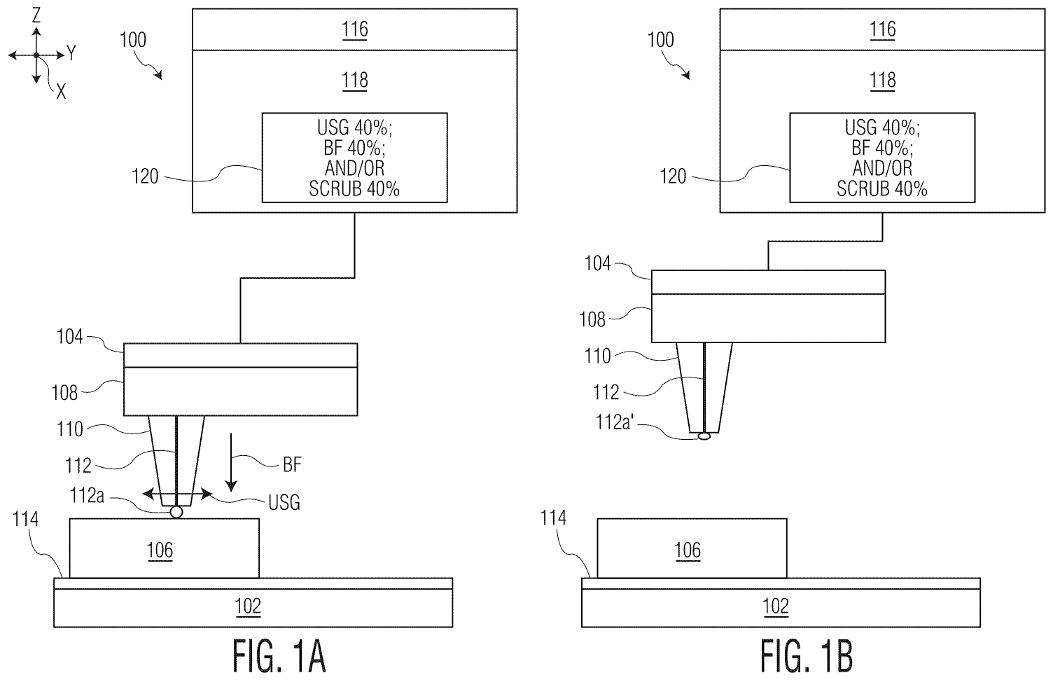

Referring now to the drawings, FIGS. 1A-1B illustrate various elements of a wire bonding system 100 in connection with a wire bonding process (e.g., a test wire bonding process). Wire bonding system 100 includes a support structure 102, and a bond head assembly 104. Bond head assembly 104 includes a transducer 108 (e.g., an ultrasonic transducer). Transducer 108 is configured to carry a wire bonding tool 110 (e.g., a capillary). Wire bonding tool 110 is configured to use a wire 112 to create a conductive structure such as a wire loop, a vertical wire structure, a conductive bump, etc. For example, in the case of a wire loop, such a wire loop may provide electrical interconnection between (i) a bonding location of a semiconductor element 106 (e.g., a bond pad of semiconductor element 106) and (ii) a bonding location of substrate 114 (e.g., a lead of a leadframe). Semiconductor element 106 (e.g., a semiconductor die) is illustrated adjacent substrate 114 and supported by support structure 102. Wire bonding system 100 is illustrated including a computer 116 and a detection system 118. Computer 116 can be programed to implement a wire bonding process (e.g., a wire bonding program). For example, wire bonding system 100 may be programmed to implement a wire bonding process using a plurality of process parameters (e.g., ultrasonic energy applied during formation of a wire bond, bonding force applied during formation of a wire bond, and table scrub energy applied during formation of a wire bond). It is generally desirable to have a robust wire bonding process where an acceptable process window is known for each of the plurality of process parameters (and/or an optimal value for each of the plurality of process parameters). According to aspects of the invention, a plurality of values of one or more process parameters are tested by detecting a response to a wire bonding process using the plurality of values of the process parameters.

Various drawings provided herein illustrate examples of values of process parameters being tested for a specific response (or a plurality of responses). Such a response may be recorded (e.g., automatically by wire bonding system 100 including computer 116).

Referring specifically to FIG. 1A, the parameter being tested may be, for example, ultrasonic energy (i.e., “USG”) applied during formation of a wire bond, bonding force (i.e., “BF”) applied during formation of a wire bond, and table scrub energy (i.e., “SCRUB”) applied during formation of a wire bond, among others. In FIG. 1A, a free air ball 112a is illustrated in contact with a bonding location of semiconductor element 106 during a wire bonding operation (e.g., a testing operation). During the bonding (or attempted bonding) of free air ball 112a to the bonding location, values of the one or more process parameters may be tested.

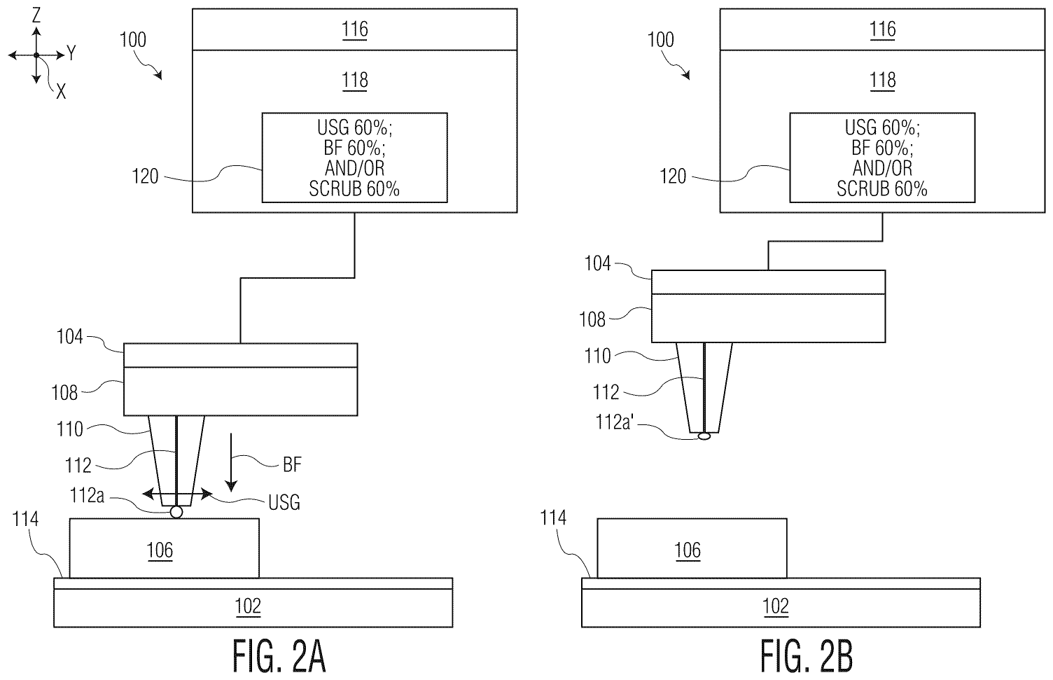

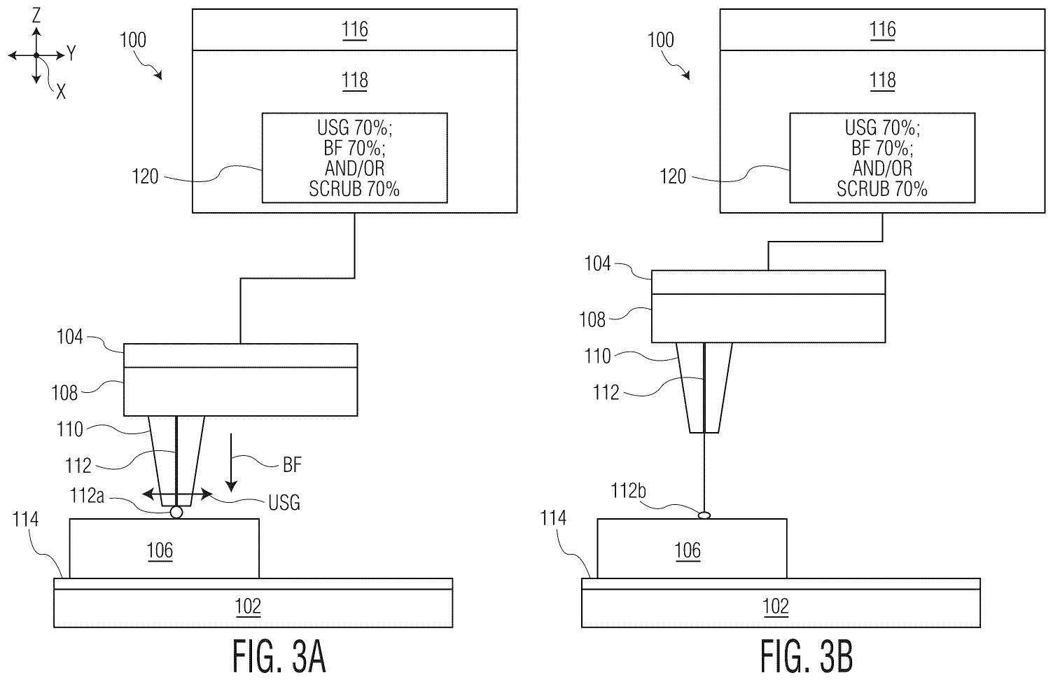

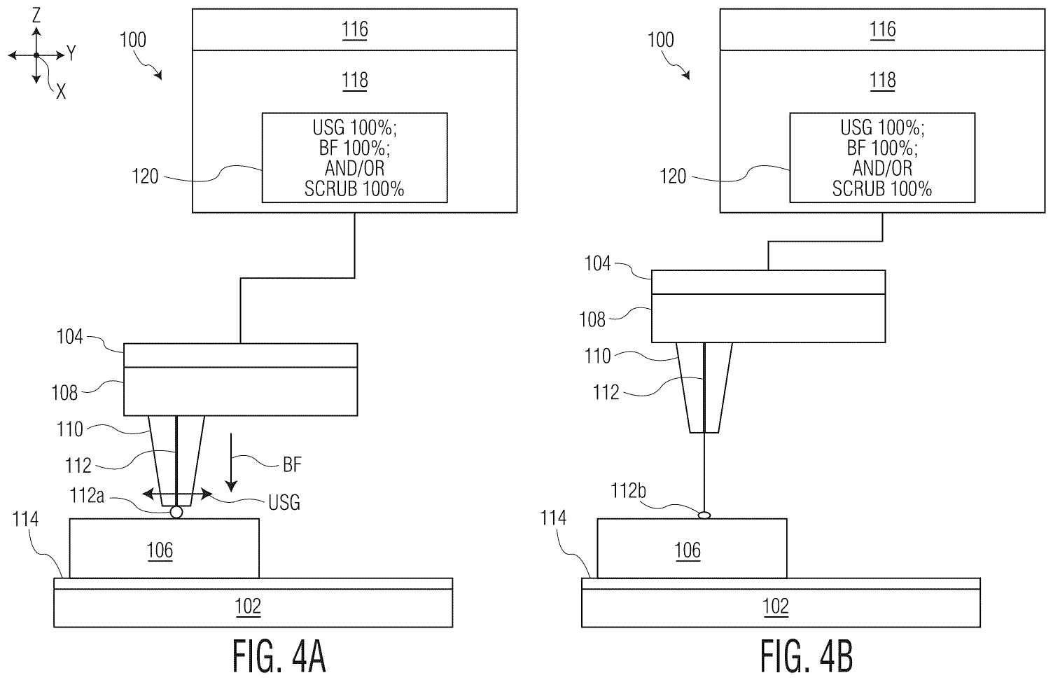

A parameter status indicator 120 (e.g., a screen, a graphical user interface, a virtual representation of a parameter status, a digital array of data, etc.) of computer 116 is shown in FIG. 1A. For example, parameter status indicator 120 illustrates that the USG value being tested is 40% of a baseline value (e.g., a predetermined setpoint). FIG. 1A also illustrates that a BF value being tested is 40% of a baseline value, and/or that a SCRUB value being tested is 40% of a baseline value. It should be understood that a single process parameter may be tested at one time. Thus, although FIG. 1A (and other figures herein) illustrates various parameters on parameter status indicator 120, it should be understood that it may be desired to test a single process parameter (e.g., USG, BF, SCRUB, etc.) one at a time. In this way, FIGS. 1A-1B, FIGS. 2A-2B, FIGS. 3A-3B, and FIGS. 4A-4B may be considered to be testing a single process parameter (e.g., USG) by detecting a response to the process parameter(s) at various values (e.g., 40% in FIGS. 1A-1B, 60% in FIGS. 2A-2B, 70% in FIGS. 3A-3B, and 100% in FIGS. 4A-4B).

In certain iterations (e.g., when testing certain values of a process parameter), free air ball 112a may not be properly bonded to a bonding location of semiconductor element 106. For example, such a condition may be referred to as a “no stick on pad” (i.e., NSOP) condition. Wire bonding systems often include detection systems (e.g., detection system 118) for detecting if a portion of wire is properly bonded to a bonding location. For example, wire bonding systems marketed by Kulicke and Soffa Industries, Inc. often utilize a “BITS” process (i.e., bond integrity test system) to confirm that proper wire bonds have been (or have not been) formed. International Patent Application Publication WO 2009/002345, which is incorporated by reference herein in its entirety, illustrates exemplary details of such processes and related systems.

Referring now to FIG. 1B, detection system 118 detects that free air ball 112a′ (i.e., a deformed free air ball) was not properly bonded to the bonding location as wire bonding tool 110 moves away from semiconductor element 106. Accordingly, using detection system 118, wire bonding system 100 can determine that the USG process parameter of 40% of a baseline value results in a ball lift condition (e.g., NSOP condition). Alternatively, wire bonding system 100 can determine that the bond force process parameter of 40% and/or the scrub amplitude process parameter of 40% results in a ball lift condition (e.g., NSOP condition).

The wire bonding process (e.g., testing process) of FIGS. 1A-1B can be repeated for a plurality of iterations (e.g., see FIGS. 2A-2B, FIGS. 3A-3B, and/or FIGS. 4A-4B) at different values of the process parameter(s). FIGS. 2A-2B illustrate a response of another ball lift condition (e.g., NSOP condition) when testing the process parameter (e.g., USG, BF, and/or SCRUB) at 60% of the baseline value. FIGS. 3A-3B illustrate a response of a wire bond 112b that is acceptable (e.g., not an NSOP condition) when testing the process parameter (e.g., USG, BF, and/or SCRUB) at 70% of the baseline value. FIGS. 4A-4B also illustrate a response of wire bond 112b that is acceptable (e.g., not an NSOP condition) when testing the process parameter (e.g., USG, BF, and/or SCRUB) at 100% of the baseline value. The response(s) to each of the tests (e.g., a ball lift condition or an acceptable wire bond condition) may be recorded (e.g., automatically).

The exemplary processes illustrated in connection with FIGS. 1A-1B, FIGS. 2A-2B, FIGS. 3A-3B, and FIGS. 4A-4B may be used to test a process window for one or more process parameters on wire bonding system 100. Table 1 illustrates various test points (i.e., values) for testing a process parameter (e.g., USG, BF, SCRUB, etc.), including those illustrated in FIGS. 1A-1B, FIGS. 2A-2B, FIGS. 3A-3B, and FIGS. 4A-4B.

TABLE 1

| | | | | | | | | |
|---|---|---|---|---|---|---|---|---|
| 1 | PROCESS PARAMETER BEING TESTED | 40% | 50% | 60% | 70% | 80% | 90% | 100% |
| | (RELATIVE TO BASELINE) | | | | | | | |
| 2 | RESPONSE | BALL | BALL | BALL | OK | OK | OK | OK |
| | | LIFT | LIFT | LIFT | | | | |

In Table 1 (row 1), a process parameter being tested (e.g., USG, BF, SCRUB, etc.) is identified. The response being recorded at each of the values of the process parameter is related to a ball lift condition (or lack thereof).

The results and/or responses of testing (e.g., using the method illustrated in FIGS. 1A-1B, FIGS. 2A-2B, FIGS. 3A-3B, and FIGS. 4A-4B) are shown in row 2 of Table 1. More specifically, there is a “ball lift” condition at 40%, 50%, and/or 60% of baseline of the process parameter (e.g., USG). A favorable response (e.g., no ball lift) is illustrated as “OK” at each test point (e.g., value of the process parameter) at and/or above 70%. Thus, a process window for the process parameter (e.g., USG) is defined as any value of the process parameter greater than or equal to 70% of the baseline USG setting. Also, an optimal value may be determined, using certain criteria (e.g., an algorithm, tolerance considerations, time/energy considerations, etc.). For example, with the results shown in Table 1, using such criteria, the optimal value may be identified at 80%.

It will be appreciated by those skilled in the art that the testing process (the results of which are summarized in row 2 of Table 1) may be conducted with many other process parameters. For example, if USG is the process parameter being tested, the testing may occur at some other level of other parameters (e.g., bond force, table scrub, etc.). According to certain embodiments of the invention, each of the testing steps and the recording steps may be repeated while varying another process parameter to test at least one response of the process parameter at the plurality of values of the process parameter, and the another process parameter.

Table 2 illustrates an example of such a process, where: the process parameter being tested may be, for example, USG, BF, SCRUB, etc.; and the response being detected is still the presence (or absence) of a ball lift condition. In a specific example, the process parameter being tested is USG. While testing the response at the plurality of values of USG (e.g., 40%, 50%, . . . 100%, etc.), it may be desirable to also vary another process parameter (e.g., a variable parameter value) and test the response. In Table 2, rows 2-4 represent varying another process parameter while testing the response to the plurality of values of USG. In an example where the another process parameter is BF (i.e., bond force), Variable Parameter Value #1 may be 90% of the baseline bond force, Variable Parameter Value #2 may be 100% of the baseline bond force, and Variable Parameter Value #3 may be 110% of the baseline bond force. Thus, by testing the response of the process parameter at the plurality of values of the process parameter (i.e., 40%-100%), and the another process parameter, one may see that the largest process window occurs at Variable Parameter Value #3 (e.g., 110% of the baseline bond force), where the USG process window is now any value of USG greater than or equal to 50% of the baseline USG setting. Also, an optimal value may be determined, using certain criteria (e.g., an algorithm, tolerance considerations, time/energy considerations, etc.). For example, with the results shown in Table 2 (using such criteria, with a BF of 110%), the optimal value for USG may be identified at 60%.

TABLE 2

| | | | | | | | | |
|---|---|---|---|---|---|---|---|---|
| 1 | PROCESS PARAMETER BEING TESTED | 40% | 50% | 60% | 70% | 80% | 90% | 100% |
| | (RELATIVE TO BASELINE) | | | | | | | |
| 2 | VARIABLE PARAMETER VALUE #1 | BALL | BALL | BALL | OK | OK | OK | OK |
| | | LIFT | LIFT | LIFT | | | | |
| 3 | VARIABLE PARAMETER VALUE #2 | BALL | BALL | OK | OK | OK | OK | OK |
| | | LIFT | LIFT | | | | | |
| 4 | VARIABLE PARAMETER VALUE #3 | BALL | OK | OK | OK | OK | OK | OK |
| | | LIFT | | | | | | |

Each of the variable parameter values may represent a parameter that can be modulated in a wire bonding operation (e.g., USG, bond force, scrub amplitude, scrub frequency, wire bonding tool velocity, wire bonding tool acceleration, etc.) and/or a setting of wire bonding system 100 (e.g., constant velocity mode, seek mode, calibration mode, etc.).

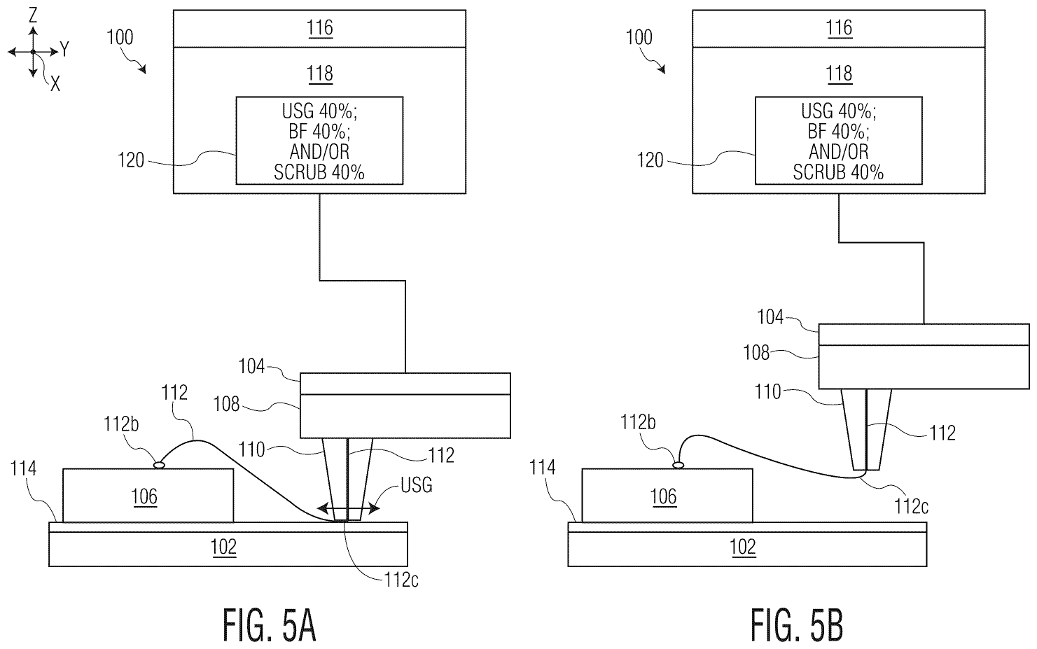

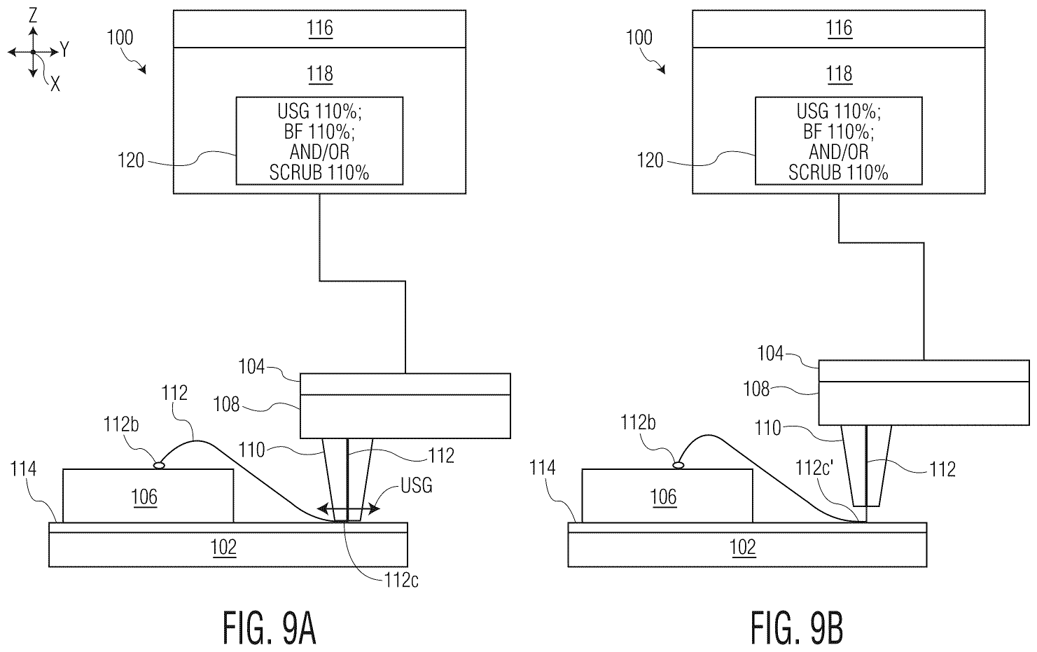

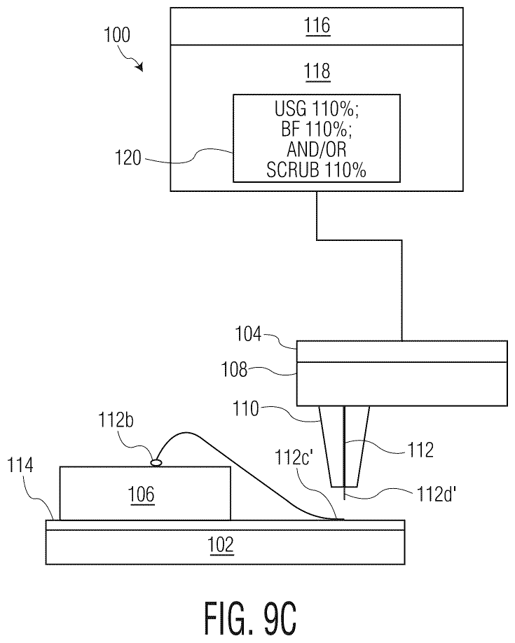

FIGS. 1A-1B, FIGS. 2A-2B, FIGS. 3A-3B, and FIGS. 4A-4B, as well as Tables 1 and 2, relate to testing a process parameter with the response being the presence (or absence) of a ball lift condition. It should be understood that the response being detected while testing a process parameter may be any desired response. For example, exemplary responses include ball lift of a ball bond, stitch lift of a stitch bond, a short tail condition, a pull value of a wire bond, a shape of a wire bond, and a dimension of a wire bond. FIGS. 5A-5B, FIGS. 6A-6B, FIGS. 7A-7C, FIGS. 8A-8C, and/or FIGS. 9A-9C relate to testing a process parameter with the response being the presence (or absence) of a stitch lift condition and/or a short tail condition.

Further, FIGS. 1A-1B, FIGS. 2A-2B, FIGS. 3A-3B, and FIGS. 4A-4B, as well as Tables 1 and 2 are described in connection with identifying an acceptable process window, where the process window has a single constraint (e.g., greater than 70% of baseline USG, greater than 60% of baseline USG, etc.) and/or a minimum threshold value. It should be understood that acceptable process windows may be identified with constraints on either end of the process window (e.g., a minimum threshold value and a maximum threshold value). Each of FIGS. 5A-5B, FIGS. 6A-6B, FIGS. 7A-7C, FIGS. 8A-8C, and/or FIGS. 9A-9C may be described in connection with such a process window.

Another wire bonding process (e.g., testing process) is illustrated in FIGS. 5A-5B. According to aspects of the invention, a plurality of values of one or more process parameters are tested by detecting a response to a wire bonding process using the plurality of values of the process parameters in FIGS. 5A-5B.

Referring specifically to FIG. 5A, the parameter being tested may be, for example, ultrasonic energy (“USG”) applied during formation of a wire bond, bonding force (i.e., “BF”) applied during formation of a wire bond, and/or table scrub energy (i.e., “SCRUB”) applied during formation of a wire bond, among others. In FIG. 5A, wire bond 112b (e.g., a bonded free air ball) is illustrated having been formed at a bonding location of semiconductor element 106 during a wire bonding operation. A length of wire 112 has been extended from wire bond 112b to a bonding location of substrate 114. In FIG. 5A, wire bonding tool 110 is illustrated attempting to bond a portion of wire 112c (e.g., a stitch bond) to the bonding location of substrate 114. Ultrasonic energy is being applied in an attempt to bond the portion of wire 112c to the bonding location (e.g., a lead) of substrate 114 (e.g., a leadframe). During the bonding (or attempted bonding) of the portion of wire 112c to the bonding location, values of one or more process parameters may be tested. As illustrated in FIG. 5A, parameter status indicator 120 illustrates that a USG value being tested is 40% of a baseline value (e.g., a predetermined setpoint), a BF value being tested is 40% of a baseline value, and/or a SCRUB value being tested is 40% of a baseline value.

In FIG. 5B, detection system 118 detects that the portion of wire 112c was not properly bonded to the bonding location as wire bonding tool 110 moves away from substrate 114. Accordingly, using detection system 118, wire bonding system 100 can determine that the process parameter (e.g., USG, BF, and/or SCRUB) at 40% of a baseline value results in a no-stick-on-lead (NSOL) condition.

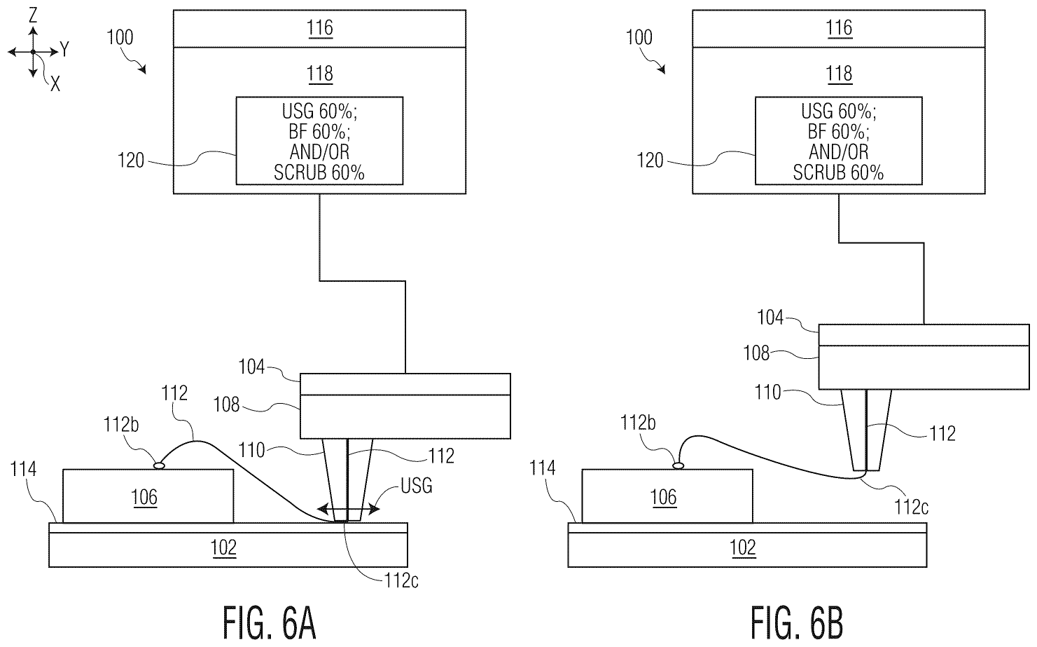

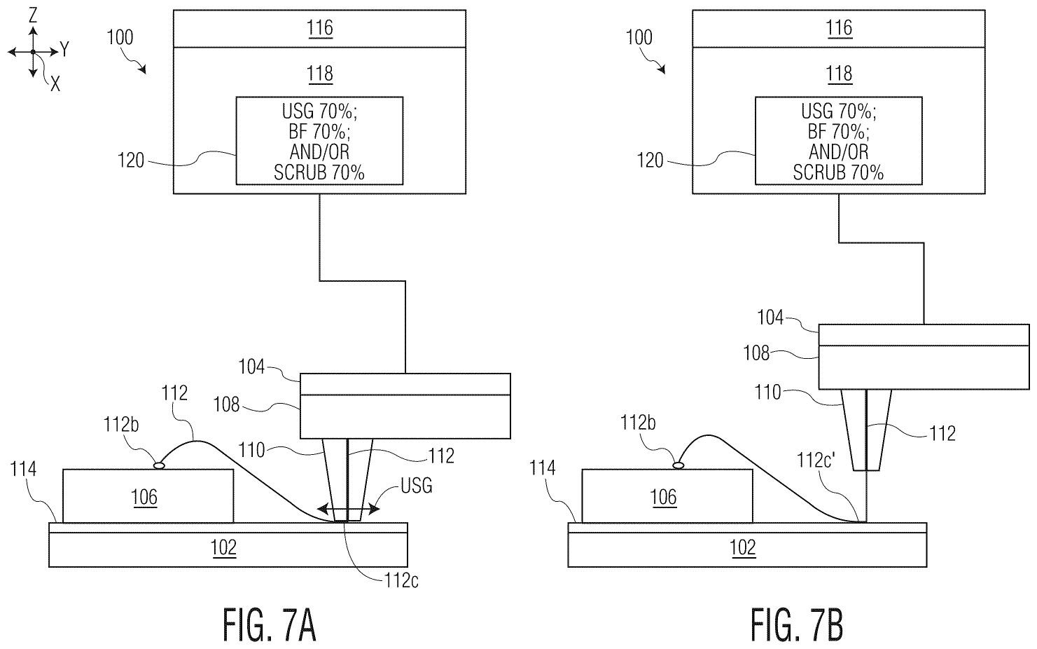

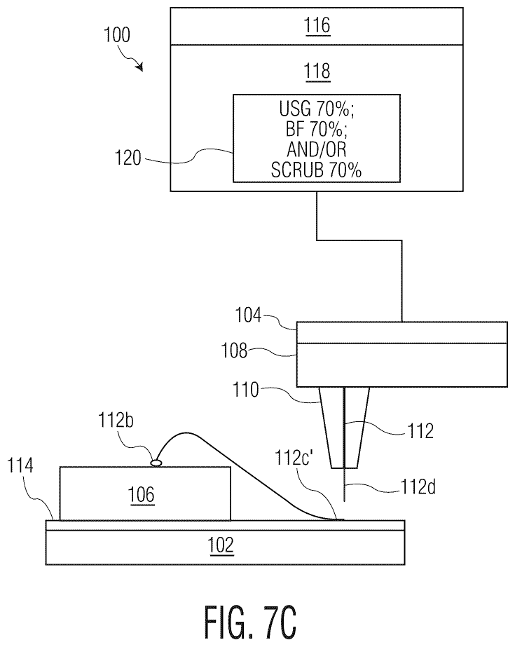

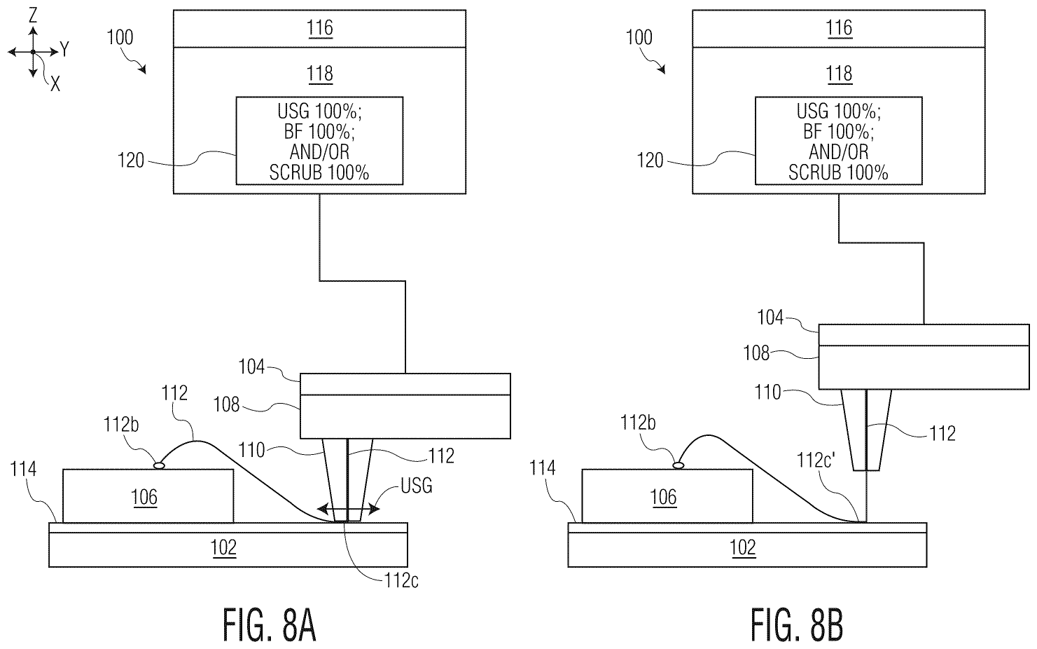

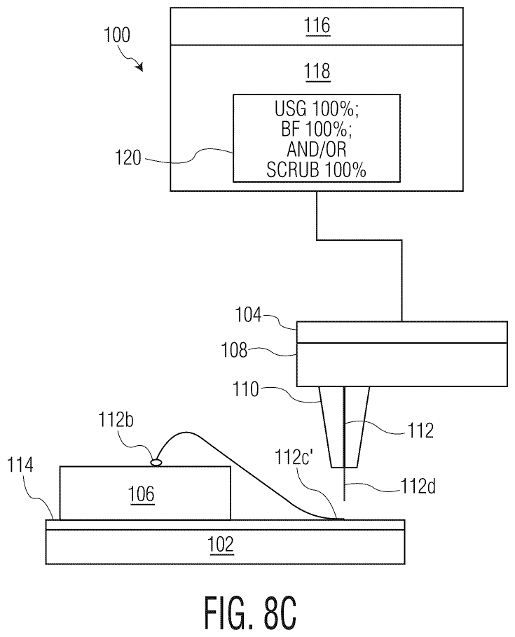

The wire bonding process (e.g., testing process) of FIGS. 5A-5B can be repeated for a plurality of iterations (e.g., see FIGS. 6A-6B, FIGS. 7A-7C, FIGS. 8A-8C, and/or FIGS. 9A-9C) at different values of the process parameter(s). FIGS. 6A-6B illustrate a response of a NSOL condition when testing the process parameter (e.g., USG, BF, and/or SCRUB) at 60% of the baseline value. FIGS. 7A-7C illustrate a response of a wire bond 112c′ that is acceptable (i.e., an acceptable stitch bond) (e.g., not an NSOL condition) when testing the process parameter (e.g., USG, BF, and/or SCRUB) at 70% of the baseline value. FIGS. 8A-8C also illustrate a response of wire bond 112c′ that is acceptable (e.g., not an NSOL condition) when testing the process parameter (e.g., USG, BF, and/or SCRUB) at 100% of the baseline value.

FIGS. 9A-9C also illustrate a response of wire bond 112c′ that is acceptable (e.g., not an NSOL condition) when testing the process parameter (e.g., USG, BF, and/or SCRUB) at 110% of the baseline value. However, as illustrated in FIG. 9C, when wire bonding tool 110 is moved upward, a short wire tail 112d′ has been formed. Accordingly, using detection system 118, wire bonding system 100 can determine that the process parameter (e.g., USG, BF, SCRUB, etc.) tested at 110% of a baseline value results in an unacceptable condition (e.g., a short tail condition). The responses to each of the tests (e.g., an NSOL condition, an acceptable wire bond condition, or a short tail condition) may be recorded (e.g., automatically).

The exemplary processes illustrated in connection with FIGS. 5A-5B, FIGS. 6A-6B, FIGS. 7A-7C, FIGS. 8A-8C, and FIGS. 9A-9C may be used to test a process window for one or more process parameters on wire bonding system 100. Table 3 illustrates various test points (i.e., values) for testing a process parameter (e.g., USG, BF, SCRUB, etc.), including those illustrated in FIGS. 5A-5B, FIGS. 6A-6B, FIGS. 7A-7C, FIGS. 8A-8C, and/or FIGS. 9A-9C.

TABLE 3

| | | | | | | | | | | |
|---|---|---|---|---|---|---|---|---|---|---|
| 1 | PROCESS PARAMETER | 40% | 50% | 60% | 70% | 80% | 90% | 100% | 110% | 120% |
| | BEING TESTED | | | | | | | | | |
| | (RELATIVE TO BASELINE) | | | | | | | | | |
| 2 | RESPONSE | NSOL | NSOL | NSOL | OK | OK | OK | OK | SHTL | SHTL |

For example, the process parameter of Table 3 may be scrub amplitude and the response is the presence (or absence) of a no-stick-on-lead (“NSOL”) condition and/or a short tail (“SHTL”) condition. The results of a testing process are shown in row 2. More specifically, there is an NSOL condition at 40%, 50%, and/or 60% of baseline of the scrub amplitude. A favorable response (e.g., no NSOL condition) is illustrated as “OK” at each test point at and/or above 70%, up until 110%, where a different unfavorable response manifests. As illustrated, there is a short tail condition at 110% and/or 120% of the baseline of the scrub amplitude. Thus, a process window for scrub amplitude is defined as any value of scrub amplitude greater than or equal to 70%, but less than or equal to 100%, of the baseline scrub amplitude value or setting. Also, an optimal value may be determined, using certain criteria (e.g., an algorithm, tolerance considerations, time/energy considerations, etc.). In the example table below, it may be desirable to provide some tolerance (e.g., +/−10%) to a parameter—and as such, the optimal value may be 80% or 90% of baseline of the scrub amplitude. In another example, the optimal value may be a midpoint of the process window (e.g., 85% of baseline of the scrub amplitude).

It will be appreciated by those skilled in the art that the testing process shown in row 2 is conducted with many other process parameters. For example, if SCRUB is the process parameter being tested, the testing will occur at some other level of other parameters (e.g., USG, BF, etc.). According to certain embodiments of the invention, each of the testing steps and recording steps may be repeated while varying another process parameter to test at least one response of the process parameter at the plurality of values of the process parameter, and the another process parameter.

Table 4 illustrates an example of such a process, where: the process parameter being tested may be, for example, USG, BF, SCRUB, etc.; and the response being detected is still the presence (or absence) of an NSOL condition and/or a short tail condition. In a specific example, the process parameter being tested is SCRUB. While testing the response at the plurality of values of SCRUB (e.g., 40%, 50%, . . . 120%, etc.), it may be desirable to also vary another process parameter (e.g., a variable parameter value) and test the response. In Table 4, rows 2-4 represent varying another process parameter while testing the response to the plurality of values of SCRUB. In an example where the another process parameter is BF (i.e., bond force), Variable Parameter Value #1 may be 90% of the baseline bond force, Variable Parameter Value #2 may be 100% of the baseline bond force, and Variable Parameter Value #3 may be 110% of the baseline bond force. Thus, by testing the response of the process parameter (e.g., SCRUB) at the plurality of values of the process parameter (i.e., 40%-120%), and the another process parameter, one may see that the largest process window occurs at Variable Parameter Value #3 (e.g., 110% of bond force), where the SCRUB process window is now any value of SCRUB greater than or equal to 50% of the baseline SCRUB setting, and less than or equal to 110% of the baseline SCRUB setting. Also, an optimal value may be determined, using certain criteria (e.g., an algorithm, tolerance considerations, time/energy considerations, etc.). For example, with the results shown in Table 4, using such criteria, with a BF of 110%, the optimal value for SCRUB may be identified at 60%, 100%, or some value in between (e.g., 80%).

TABLE 4

| | | | | | | | | | | |
|---|---|---|---|---|---|---|---|---|---|---|
| 1 | PROCESS PARAMETER | 40% | 50% | 60% | 70% | 80% | 90% | 100% | 110% | 120% |
| | BEING TESTED | | | | | | | | | |
| | (RELATIVE TO BASELINE) | | | | | | | | | |
| 2 | VARIABLE PARAMETER | NSOL | NSOL | NSOL | OK | OK | OK | OK | SHTL | SHTL |
| | VALUE #1 | | | | | | | | | |
| 3 | VARIABLE PARAMETER | NSOL | NSOL | OK | OK | OK | OK | OK | SHTL | SHTL |
| | VALUE #2 | | | | | | | | | |
| 4 | VARIABLE PARAMETER | NSOL | OK | OK | OK | OK | OK | OK | OK | SHTL |
| | VALUE #3 | | | | | | | | | |

Each of the variable parameter values may represent a parameter that can be modulated in a wire bonding operation (e.g., USG, bond force, scrub amplitude, scrub frequency, wire bonding tool velocity, wire bonding tool acceleration, etc.) and/or a setting of wire bonding system 100 (e.g., constant velocity mode, seek mode, calibration mode, etc.).

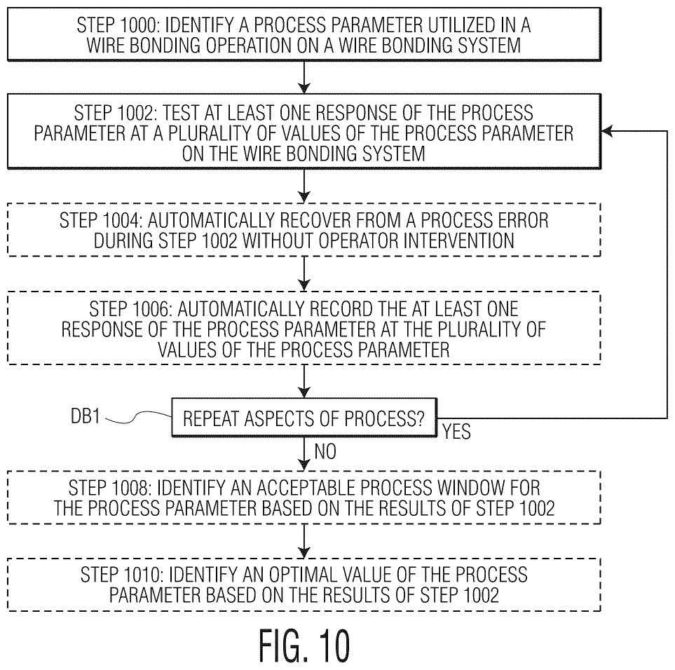

FIG. 10 is a flow diagram of a method of testing a process window for a process parameter on a wire bonding system (e.g., wire bonding system 100). As is understood by those skilled in the art, certain steps included in the flow diagram may be omitted; certain additional steps may be added; and the order of the steps may be altered from the order illustrated-all within the scope of the invention.

At Step 1000, a process parameter utilized in a wire bonding operation on a wire bonding system is identified (e.g., see process parameters identified and/or illustrated in parameter status indicator 120 of wire bonding system 100 of FIGS. 1A-1B, FIGS. 2A-2B, FIGS. 3A-3B, FIGS. 4A-4B, FIGS. 5A-5B, FIGS. 6A-6B, FIGS. 7A-7C, FIGS. 8A-8C, and/or FIGS. 9A-9C). At Step 1002, at least one response of the process parameter is tested at a plurality of values of the process parameter on the wire bonding system (e.g., see testing process of FIGS. 1A-1B, FIGS. 2A-2B, FIGS. 3A-3B, FIGS. 4A-4B, FIGS. 5A-5B, FIGS. 6A-6B, FIGS. 7A-7C, FIGS. 8A-8C, and/or FIGS. 9A-9C). In certain embodiments, the process parameter relates to at least one of ultrasonic energy applied during formation of a wire bond, bonding force applied during formation of a wire bond, and table scrub energy applied during formation of a wire bond (e.g., see USG, BF and SCRUB references in FIG. 1A, FIG. 2A, FIG. 3A, FIG. 4A, FIG. 5A, FIG. 6A, FIG. 7A, FIG. 8A, and/or FIG. 9A). In certain exemplary embodiments, the wire bond may be: a first wire bond of a wire loop; a second wire bond of a wire loop; an intermediate wire bond of a wire loop (e.g., a wire bond between an initial wire bond and a final wire bond in a wire loop); a conductive bump bond; a ball bond of a wire loop; a stitch bond of a wire loop; and/or a wire bond of a vertical wire structure (e.g., where only one end of the vertical wire structure is bonded to a workpiece). In certain exemplary embodiments, the at least one response relates to ball lift of the ball bond, stitch lift of a stitch bond, a short tail condition, a pull value of a wire bond, a shape of a wire bond, and/or a dimension of a wire bond. In certain embodiments, Step 1002 is conducted automatically (e.g., without machine stop; without operator intervention; etc.).

In certain exemplary embodiments, at optional Step 1004, the wire bonding system automatically recovers from a process error during Step 1002 without operator intervention. By automatically recovering from the process error, the method of testing of the process window may continue without operator intervention.

In certain exemplary embodiments, the step of automatically recovering from a process error includes recovering from a ball lift condition. For example, the recovery from a ball lift condition may include: (a1) bonding a lifted ball to another location; and (b1) continuing with the testing of the process window after bonding the lifted ball to another location. Further, after step (a1), predetermined parameters may be utilized for forming a wire tail after bonding the lifted ball in step (a1).

In certain exemplary embodiments, the step of automatically recovering from a process error includes recovering from a stitch lift condition. For example, the recovery from a stitch lift condition may include: (a2) bonding a lifted stitch to another location; and (b2) continuing with the testing of the process window after bonding the lifted stitch to another location. Further, after step (a2), predetermined parameters may be utilized for forming a wire tail after bonding the lifted stitch in step (a2).

In certain exemplary embodiments, the step of automatically recovering from a process error includes recovering from a short tail condition. For example, predetermined parameters may be utilized for forming a wire tail in connection with the recovery from a short tail condition.

U.S. Pat. Nos. 8,899,469 and 9,165,842 illustrate exemplary techniques for recovering from certain error conditions, and for forming a wire tail in connection with such recovery. The contents of such patents are incorporated by reference herein in their entirety.

At optional Step 1006, the at least one response of the process parameter at the plurality of values of the process parameter is automatically recorded (e.g., without machine stop; without operator intervention; etc.). At decision block DB1, a determination is made as to whether certain aspects of the method (e.g., each of Step 1002, Step 1004, and/or Step 1006) are repeated for a predetermined number of iterations. If “Yes” is the answer at decision block DB1, some aspect of the testing method is repeated, for example, as described in the next two paragraphs.

For example, it may be desirable to repeat Step 1002 (and/or Steps 1004 and 1006 if desired) for a predetermined number of iterations. By repeating Step 1002, a more accurate process window may be determined for the subject process parameter, and/or a more accurate optimal value may be determined for the process parameter.

In another example, it may be desirable to repeat Step 1002 (and/or Steps 1004 and 1006 if desired) for a predetermined number of iterations while varying another process parameter to test the at least one response of the process parameter at the plurality of values of the process parameter, and the another process parameter, on the wire bonding system. For example, see the description of Tables 2 and 4 above, where another process parameter is varied while testing the subject process parameter. By repeating Step 1002, for a predetermined number of iterations while varying another process parameter: a more accurate process window may be determined for the subject process parameter; a more accurate optimal value may be determined for the process parameter; and/or a more accurate value for the another process parameter may be determined.

If “No” is the answer at decision block DB1, the process proceeds to Step 1008. At optional Step 1008, an acceptable process window for the process parameter is identified based on the results of Step 1002 (e.g., including repeated iterations of Step 1002, if any). A desirable value of the another process parameter may also identified (e.g., after repeated Step 1002, Step 1004, and/or Step 1006).

At optional Step 1010, an optimal value of the process parameter is identified based on the results of Step 1002 (e.g., including repeated iterations of Step 1002, if any). A desirable value of the another process parameter may also identified (e.g., after repeated Step 1002, Step 1004, and/or Step 1006).

While the invention is described primarily with respect to testing a process window for specific process parameters on a wire bonding system (e.g., USG, BF, SCRUB), the invention is not limited thereto. Different and/or additional process parameters (and different and/or additional responses) are contemplated within the scope of the invention.

Although the invention is illustrated and described herein with reference to specific embodiments, the invention is not intended to be limited to the details shown. Rather, various modifications may be made in the details within the scope and range of equivalents of the claims and without departing from the invention.

1. A method of testing a process window for a process parameter on a wire bonding system, the method comprising the steps of:
(a) identifying the process parameter utilized in a wire bonding operation on the wire bonding system;
(b) testing at least one response of the process parameter at a plurality of values of the process parameter on the wire bonding system; and
(c) automatically recording the at least one response of the process parameter at the plurality of values of the process parameter.

2. The method of claim 1 further comprising a step of (d) identifying an acceptable process window for the process parameter based on the results of step (b).

3. The method of claim 1 further comprising a step of identifying an optimal value of the process parameter based on the results of step (b).

4. The method of claim 1 further comprising a step of automatically recovering from a process error during step (b) without operator intervention.

5. The method of claim 4 wherein the step of automatically recovering from a process error includes at least one of recovering from a ball lift condition, recovering from a stitch lift condition, and recovering from a short tail condition.

6. The method of claim 1 wherein the process parameter relates to at least one of ultrasonic energy applied during formation of a wire bond, bonding force applied during formation of a wire bond, and table scrub energy applied during formation of a wire bond.

7. The method of claim 6 wherein the wire bond is selected from the group consisting of a first wire bond of a wire loop, a second wire bond of a wire loop, an intermediate wire bond of a wire loop, a conductive bump bond, and a wire bond of vertical wire structure.

8.-23. (canceled)

24. A method of testing a process window for a process parameter on a wire bonding system, the method comprising the steps of:
(a) identifying the process parameter utilized in a wire bonding operation on the wire bonding system;
(b) testing at least one response of the process parameter at a plurality of values of the process parameter on the wire bonding system; and
(c) identifying an acceptable process window for the process parameter based on the results of step (b).

25. The method of claim 24 further comprising a step of automatically recording the at least one response of the process parameter at the plurality of values of the process parameter.

26. The method of claim 24 further comprising a step of identifying an optimal value of the process parameter based on the results of step (b).

27. The method of claim 24 further comprising a step of automatically recovering from a process error during step (b) without operator intervention.

28. The method of claim 27 wherein the step of automatically recovering from the process error includes at least one of recovering from a ball lift condition, recovering from a stitch lift condition, and recovering from a short tail condition.

29. The method of claim 24 wherein the process parameter relates to at least one of ultrasonic energy applied during formation of a wire bond, bonding force applied during formation of a wire bond, and table scrub energy applied during formation of a wire bond.

30. The method of claim 29 wherein the wire bond is selected from the group consisting of a first wire bond of a wire loop, a second wire bond of a wire loop, an intermediate wire bond of a wire loop, a conductive bump bond, and a wire bond of vertical wire structure.

31.-46. (canceled)

47. A method of testing a process window for a process parameter on a wire bonding system, the method comprising the steps of:
(a) identifying the process parameter utilized in a wire bonding operation on a wire bonding system;
(b) testing at least one response of the process parameter at a plurality of values of the process parameter on the wire bonding system; and
(c) identifying an optimal value of the process parameter based on the results of step (b).

48. The method of claim 47 further comprising a step of (d) identifying an acceptable process window for the process parameter based on the results of step (b).

49. The method of claim 47 further comprising a step of automatically recording the at least one response of the process parameter at the plurality of values of the process parameter.

50. The method of claim 47 further comprising a step of automatically recovering from a process error during step (b) without operator intervention.

51. The method of claim 50 wherein the step of automatically recovering from the process error includes at least one of recovering from a ball lift condition, recovering from a stitch lift condition, and recovering from a short tail condition.

52. The method of claim 47 wherein the process parameter relates to at least one of ultrasonic energy applied during formation of a wire bond, bonding force applied during formation of a wire bond, and table scrub energy applied during formation of a wire bond.

53.-69. (canceled)
